(19) United States
(12) Patent Application Publication
(10) Pub. No.: US 2011/0197962 A1
(43) Pub. Date: Aug. 18, 2011

(54) BARRIER LAMINATE AND PROTECTION SHEET FOR SOLAR CELL

(76) Inventor: Hiroshi KAWAKAMI, Ashigarakami-gun (JP)

(21) Appl. No.: 13/028,801

(22) Filed: Feb. 16, 2011

(30) Foreign Application Priority Data
Feb. 17, 2010 (JP) 2010-032167

(51) Int. Cl. H01L 31/0216; H01L 31/18; B05D 1/36

(52) U.S. Cl. 136/256; 427/407.1; 427/248.1

(57) ABSTRACT

Provided is a barrier laminate which comprises a polyester substrate film, an organic layer directly on the surface of the polyester substrate film and an inorganic layer directly on the surface of the organic layer, wherein the organic layer comprises polymer material having a glass-transition temperature of 40° C. or more as the main component.

### CROSS-REFERENCE TO RELATED APPLICATIONS

The present application claims the benefit of priority from Japanese Patent Application No. 032167/2010, filed on Feb. 17, 2010, the contents of which are herein incorporated by reference in their entirety.

### FIELD OF THE INVENTION

The present invention relates to a barrier laminate and a protection sheet for a solar cell using the barrier laminate.

### DESCRIPTION OF THE RELATED ART

Heretofore, protection sheets for a solar cell have been widely investigated. For example, JP-A-2009-38236 discloses a back film for a solar cell comprising a weather-resistant substrate, a primer layer and a deposit layer. JP-A-2008-227203 discloses a protection sheet for a solar cell comprising a substrate film having weatherability and hydrolysis resistance, a transparent primer layer and a deposit layer consisting of an inorganic compound. JP-A-2009-10269 discloses a back sheet for a solar cell comprising a transparent primer layer, a deposit layer consisting of an inorganic compound and an overcoat layer which are formed on an adhesive coat agent coated on a substrate film.

Thus-mentioned above, known protection sheets for a solar cell comprise a structure in which an organic layer and an inorganic layer adjacent to the organic layer are laminated in a substrate film. Such a protection sheet for a solar cell, however, is used under environment in which the temperature changes highly or low alternately, and therefore, it has a serious problem in reduction of barrier property. It is desired to inhibit the gas barrier property thereof from being deteriorated under such an environment.

In addition, since solar cells are utilized from the viewpoint of environmental protection, it is strongly desired that such solar cells can be produced by an environmentally friendly production method. In known-protection sheets for a solar cell, however, an organic layer such as a transparent primer layer was generally provided by coating an organic solvent solution on a substrate film, and therefore, such known-protection sheets for a solar cell are not environmentally friendly.

### SUMMARY OF THE INVENTION

An object of the invention is to solve the above problem, and to provide a barrier laminate of which barrier property hardly deteriorates even if the barrier laminate is repeatedly used under a high temperature and a low temperature alternately. Another object of the invention is to provide a protection sheet for a solar cell using the barrier laminate of which barrier property hardly deteriorates even if the protection sheet is repeatedly used under a high temperature and a low temperature alternately.

The inventor has investigated and found that a protection sheet comprising a barrier laminate consisting of three layers which are a plastic substrate film, an organic layer and an inorganic layer is suitable for forming a protection sheet for a solar cell having high performance at low cost. Herein, if the thickness of an inorganic layer as a barrier layer is thin, for example, 100 nm or less, the production cost of the barrier laminate can be decreased. However, the thinner thickness of the inorganic layer tends to influence the barrier property of the protection sheet for a solar cell. In order to improve the regard, a composition of the organic layer in the barrier laminate may be changed. Solar cells, however, are repeatedly exposed to high day temperature and low night temperature. The inventor investigated durability of the barrier laminate of the above three layer-structure according to the heat cycle test, IEC61215/61646. The inventor found that, in the back sheet for a solar cell comprising the barrier laminate of the above three layer-structure, only controlling the organic layer of the barrier laminate cannot attain sufficient durability. Therefore, the barrier property of the barrier laminate remarkably deteriorates.

The inventor further investigated and found that the above problems can be solved by using polyester as a substrate film and a polymer material having a grass-transition temperature of 40° C. or more as a main ingredient of the organic layer.

Specifically, the aforementioned problem can be solved by the following means.

[1] A barrier laminate comprising a polyester substrate film, an organic layer directly on the surface of the polyester substrate film and an inorganic layer directly on the surface of the organic layer, wherein the organic layer comprises a polymer material having a glass-transition temperature of 40° C. or more as the main component.
[2] A protection sheet for a solar cell comprising a barrier laminate according to [1].
[3] The protection sheet for a solar cell according to [2], wherein the polymer material in the organic layer is polyester.
[4] The protection sheet for a solar cell according to [2], wherein the polymer material in the organic layer is aromatic polyester.
[5] The protection sheet for a solar cell according to any one of [2] to [4], wherein the polyester substrate film comprises aromatic polyester.
[6] The protection sheet for a solar cell according to [2], wherein the polymer material in the organic layer is aromatic polyester and the polyester substrate film comprises aromatic polyester.
[7] The protection sheet for a solar cell according to any one of [2] to [6], wherein the inorganic layer comprises silicon oxide, aluminium oxide, or a mixture thereof as the main component.
[8] The protection sheet for a solar cell according to any one of [2] to [7], wherein the polyester substrate film comprises polyethylene terephthalate and/or polyethylene naphthalate.
[9] The protection sheet for a solar cell according to any one of [2] to [8], wherein the organic layer has a thickness of 0.1 to 3 μm.
[10] The protection sheet for a solar cell according to any one of [2] to [9], wherein the inorganic layer has a thickness of 30 to 200 nm.
[11] The protection sheet for a solar cell according to any one of [2] to [10], wherein the substrate film has a thickness of 50 to to 200 μm.
[12] The protection sheet for a solar cell according to any one of [2] to [8], wherein the organic layer has a thickness of 0.1 to 3 μm, the inorganic layer has a thickness of 30 to 200 nm, and the substrate film has a thickness of 50 to to 200 μm.
[13] The protection sheet for a solar cell according to any one of [2] to [12], wherein the polymer material in the organic layer has a glass-transition temperature of 60 to 120° C.
[14] The protection sheet for a solar cell according to any one of [2] to [13], wherein the organic layer has a thickness of 0.1 to 3 μm, the inorganic layer has a thickness of 30 to 200 nm, the substrate film has a thickness of 50 to to 200 μm, the polymer material in the organic layer is aromatic polyester, and the polyester substrate film comprises aromatic polyester.
[15] The protection sheet for a solar cell according to any one of [2] to [14], which further comprises a second barrier laminate comprising a polymer substrate film, an organic layer directly on the surface of the polymer substrate film and an inorganic layer directly on the surface of the organic layer; and wherein the inorganic layer of the barrier laminate and the inorganic layer of the second barrier laminate face to each other.
[16] The protection sheet for a solar cell according to [15], wherein the polymer substrate is a polyester substrate film.
[17] The protection sheet for a solar cell according to any one of [1] to [16], which is free from organic solvent.
[18] A solar cell device comprising the protection sheet for a solar cell according to any one of [2] to [17].
[19] A method for manufacturing a protection sheet for a solar cell to any one of [2] to [17], which comprises applying a composition for an organic layer on a substrate film.
[20] The method for manufacturing a protection sheet for a solar cell according to Claim 19, which comprises forming the inorganic layer by vapor deposition method.

The invention made it possible to provide a barrier laminate and a protection sheet for a solar cell, of which barrier property hardly deteriorates even if they are placed under an environment in which high temperature and low temperature are repeated alternately.

### BRIEF DESCRIPTION OF THE DRAWINGS

FIG. 1 is a schematic view showing one example of the embodiment of the barrier laminate of the invention, wherein 1 shows a barrier laminate, 2 shows a polyester substrate film, 3 shows an organic layer, and 4 shows an inorganic layer.

FIG. 2 is a schematic view showing one example of the embodiment of the barrier laminate of the invention, wherein 2 shows a polyester substrate film, 3 shows an organic layer, and 4 shows an inorganic layer.

FIG. 3 is a schematic view showing one example of the embodiment of the protection sheet for a solar cell of the invention, wherein 1 shows a barrier laminate, 2 shows a polyester substrate film, 3 shows an organic layer, 4 shows an inorganic layer, 5 shows an adhesive layer, 11 shows a barrier laminate, 21 shows a polymer substrate film, 31 shows an organic layer and 41 shows an inorganic layer.

### BEST MODE FOR CARRYING OUT THE INVENTION

The contents of the invention are described in detail hereinunder. In this description, the numerical range expressed by the wording “a number to another number” means the range that falls between the former number indicating the lowermost limit of the range and the latter number indicating the uppermost limit thereof.

The barrier laminate of the invention comprises a structure consisting of a polyester substrate film, an organic layer directly on the surface of the polyester substrate film, and an inorganic layer directly on the surface of the organic layer in that order, and has a feature in that the organic layer comprises a polymer material having a grass-transition temperature of 40° C. or more as a main ingredient of the organic layer.

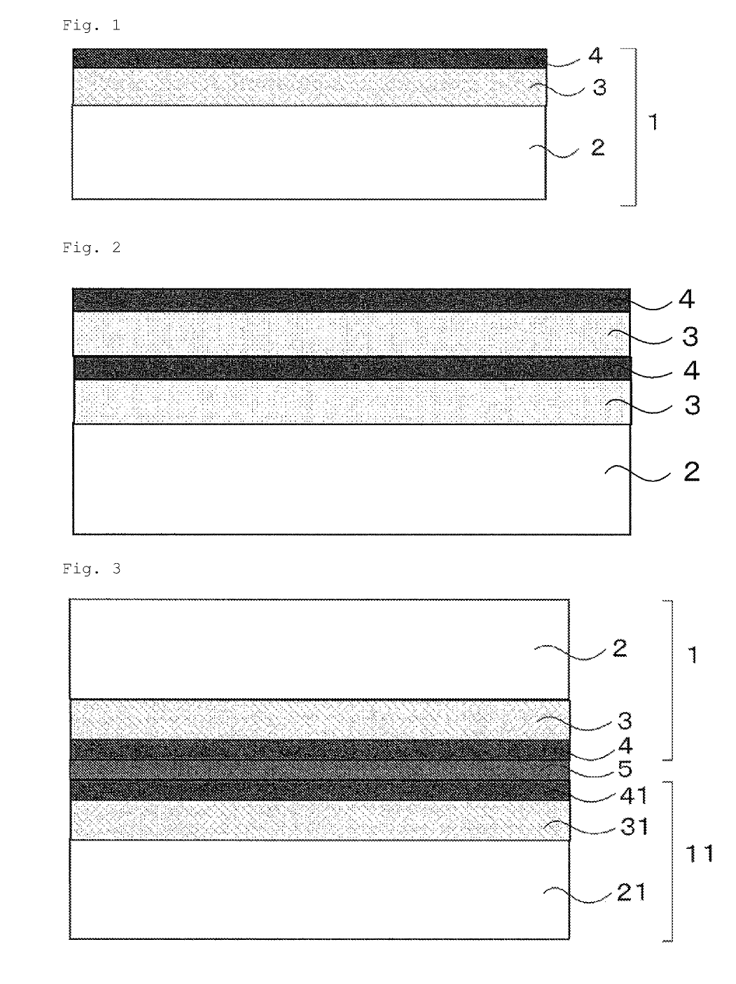

FIG. 1 shows one example of a barrier laminate 1 of the invention, wherein the barrier laminate consists of a polyester substrate film 2, an organic layer 3 provided on the surface of the polyester substrate film, an inorganic layer 4 provided on the surface of the organic layer. The barrier laminate may comprise one organic layer and one inorganic layer, or may comprise two organic layers and two inorganic layers as shown in FIG. 2. Of course, the barrier laminate may comprise three or more organic layers and three or more inorganic layers. The upper limit of the layer number is not defined, however, the layer number is generally 20 layers or less.

Such a barrier laminate is preferably used for a protection sheet for a solar cell. FIG. 3 shows a protection sheet for a solar cell comprising a barrier laminate 1 of the present invention (a first barrier laminate) and a barrier laminate 11 (a second barrier laminate). In FIG. 3, 21 shows a polymer substrate film, 31 shows an organic layer and 41 shows an inorganic layer. The first barrier laminate 1 and the second barrier laminate 2 are stuck to each other through an adhesive layer 5 so that the inorganic layer sides face to each other. The second barrier laminate 11 may be a known barrier laminate, or the barrier laminate of the invention, preferably the barrier laminate of the invention.

Hereunder, those structures are described in further detail.

### Polyester Substrate Film

In the invention, polyester film is used as a substrate film. Heretofore, as the substrate film, various kinds of plastic films have been employed. However, the kind of the plastic film has not been specifically defined. The invention, however, achieved improvement of the barrier property of the barrier laminate by using a polyester substrate film.

Kinds of the polyester used in the polyester substrate film are not specifically limited. The polyester is preferably aromatic polyester, more preferably polyethylene terephthalate (PET), polymethylene terephthalate (PTT), polybutylene terephthalate (PBT), and polyethylene naphthalate (PEN), further more preferably PET and PEN. Two or more kinds of polyesters may be mixed.

The number average molecular weight of the polyester is preferably 13,000 to 50,000, more preferably 15,000 to 35,000.

The thickness of the polyester substrate film is preferably 50 μm to 200 μm, more preferably 100 μm to 200 μm. By setting the film thickness to such a range, dimensional stability of the obtained barrier laminate is improved and knick of the obtained barrier laminate is hardly caused, to therefore be able to provide a barrier laminate having stable barrier property.

When the protection sheet for a solar cell of the invention is used as a back sheet for the solar cell, whitening agent may be added to the polyester substrate film. The whitening agent applicable herein may be an inorganic white material such as titanium oxide and silicon oxide, an organic white pigment and an organic white dye, preferably an inorganic white material, more preferably silicon oxide.

The amount to be added of the whitening agent is preferably 0.5 to 60.0 g/m², more preferably 1.0 to 50.0 g/m² to the polyester substrate film. The whitening agent is preferably particles, more preferably particles having an average particle size of 100 nm to 30 nm.

### Organic Layer

In the invention, on the surface of the polyester substrate film, provided is an organic layer comprising a polymer material having a grass-transition temperature of 40° C. or higher as a main ingredient. The main ingredient means the ingredient which is contained in the largest amount in the organic layer, generally an ingredient occupying 90% by weight or more of the organic layer, preferably an ingredient occupying 97% by weight or more of the organic layer.

The polymer material having a grass-transition temperature of 40° C. or higher is preferably a polymer material having a grass-transition temperature of 40° C. to 150° C., more preferably a polymer material having a grass-transition temperature of 60° C. to 120° C. Examples of the polymer material preferably used in the invention include acrylic resin, polyester, polyester-urethane, polyamide and polyimide. The polymer material is preferably polyester, more preferably aromatic polyester. The aromatic polyester is further more preferably polyethylene terephthalate (PET), polymethylene terephthalate (PTT), polybutylene terephthalate (PBT), and polyethylene naphthalate (PEN).

In the invention, it is particularly preferred that both of the polymer material used in the substrate film and the polymer material used in the organic layer comprises aromatic polyester. In such a case, the aromatic polyester used in the substrate film may be the same as or different from the aromatic polyester used in the organic layer.

One kind or two or more kinds of the polymer materials may used herein.

The organic layer may be formed by a known method. For example, a composition comprising photopolymerizable monomers is coated on the polyester substrate film and irradiated with ultraviolet ray, to thereby form an organic layer. Or, a resin which was dispersed into a solvent is coated on the polyester substrate film and dried, to thereby form an organic layer. In the invention, for forming an organic layer, aqueous latex in which the polymer material is dispersed into an aqueous dispersion medium may be applied on a substrate, and then heated and dried at a temperature of 100° C. or higher to evaporate and remove the aqueous dispersion medium. Such an embodiment makes it possible to product the barrier laminate at environmentally friendly condition. A composition for forming an aqueous latex layer preferably comprises 20 to 50% by weight of the polymer material and 80 to 50% by weight of the aqueous dispersion medium. The composition may comprise an ingredient other than the above ingredients. A crosslinking agent may be contained. The addition of the crosslinking agent makes it possible to form a layer of a crosslinked polymer material. As the crosslinking agent is exemplified by acrylate, polyfunctional isocyanate, and carbodiimide.

The thickness of the organic layer is preferably 0.1 to 3.0 μm, more preferably 0.5 to 2.0 μm, further more preferably 0.6 to 1.2 μm.

### Inorganic Layer

The inorganic layer is, in general, a layer of a thin film formed of a metal compound. For forming the inorganic layer, employable is any method capable of producing the intended thin film. For it, for example, suitable are physical vapor deposition methods (PVD) such as vapor evaporation method, sputtering method, ion plating method; various chemical vapor deposition methods (CVD); liquid phase growth methods such as plating or sol-gel method. Not specifically defined, the component to be in the inorganic layer may be any one satisfies the above-mentioned requirements. For example, it includes metal oxides, metal nitrides, metal carbides, metal oxide-nitrides, or metal oxide-carbides. Preferably used are oxides, nitrides, carbide oxide-nitrides, or oxide-carbides comprising at least one metal selected from Si, Al, In, Sn, Zn, Ti, Cu, Ce and Ta. Of those, preferred are oxides, nitrides carbide oxide-nitrides, or oxide-carbides of a metal selected from Si, Al, In, Sn, Zn and Ti; more preferred are metal oxides, nitrides or oxide-nitrides with Si or Al. These may contain any other element as a subsidiary component.

Preferably, the surface smoothness of the inorganic layer formed in the invention is 0.05 to 10 1 nm in terms of the mean roughness (Ra value) in 1 μm square, more preferably 0.1 to 5 nm, further more preferably 0.1 to 3 nm. The Ra of the inorganic oxide layer can be achieved by using a smooth substrate or a smooth undercoat layer. Preferred is to provide a smooth undercoat layer from the view point of ready availability and handability. The smooth undercoat layer can be obtained by coating an organic material.

Not specifically defined, the thickness of the inorganic layer is generally within a range of from 30 to 200 nm/layer, preferably from 50 to 150 nm/layer, further more preferably from 60 to 100 nm/layer. By setting the film thickness to 30 nm or more, the obtained layer has a more uniform thickness, to thereby enhance its function as a gas barrier layer. By setting the film thickness to 200 nm or less, flexibility of the obtained thin film can be sufficiently achieved, to thereby effectively suppress the thin film from being damaged due to external force such as bending or tension. The inorganic layer may have a laminate structure consisting of plural sub-layers.

### Adhesive Layer

In the invention, the first barrier laminate and the second barrier laminate are positioned through the adhesive layer so that both of the inorganic layer in the first barrier laminate and the inorganic layer in the second barrier laminate face to each other. Herein, the adhesive layer is a layer comprising an adhesive as a main ingredient, generally a layer comprising an adhesive in an amount of 70% by weight or more, preferably a layer comprising an adhesive in an amount of 80% by weight or more. The adhesive is not specifically limited for its kind. The adhesive is preferably a wet lamination adhesive, a hot melt lamination adhesive, a dry lamination adhesive, and a non-solvent adhesive. For obtaining an adhesive layer having a desired thickness, the adhesive is more preferably a wet lamination adhesive and a dry lamination adhesive. For lowering a residual amount of solvent in the obtained film, the adhesive is more preferably a dry lamination adhesive. Examples of the dry lamination adhesive include an adhesive which uses a thermal plastic resin such as vinyl acetate series, acryl resin series, vinyl chloride series, polyamide series, polyvinyl acetal series, or amorphous polyester series, an adhesive which uses rubber elastomer such as chloroprene rubber, nitrile rubber, and styrene-butadiene rubber, and an adhesive which utilizes a crosslinking reaction such as polyurethane series. From the viewpoints of ready availability of the material, handability thereof and adhesive property thereof, preferable is a polyurethane series adhesive.

The polyurethane series adhesive is classified by one-component reacting type adhesions and two-component reacting type adhesions, and it is preferably the two-component reacting type adhesion in view of stability of the adhesion strength and pot life. In addition, the two-component reacting type adhesion gives less influence on bubble release of carbon dioxide. The two-component reacting type adhesion is exemplified by an adhesion which cures polyester polyol and diisocyanate and an adhesion which cures polyether polyol and diisocyanate.

Since solar cells are used outdoors, the adhesive is preferably composed of a weather-resistant material. The adhesion is desired to maintain its adhesion force after its environmental test is carried out in addition to its initial adhesion force. Protection sheets for a solar cell are generally required to be preserved in the state for not less than 2000 hours at 85° C. at relative humidity (RH) of 85%, as their general acceleration evaluation. The state corresponds to the physical value when such a sheet is maintained in the state for 168 hours at 105° C. at RH of 100%.

The thickness of the adhesive layer is preferably 2 μm to 10 μm, more preferably 3 μm to 8 μm, further more preferably 4 to 6 μm.

### Other Functional Layer

The protection sheet for a solar cell of the invention may comprise another functional layer without diverting the scope of the gist of the invention. The protection sheet for a solar cell, for example, may comprise another resin film. Such a resin film, for example, may be used for ensuring insulation property of the protection sheet for a solar cell, especially for ensuring partially discharge of voltage. The resin film used for such a use preferably has a total film thickness of 300 μm or more in the case where the partially discharge of voltage is 1000 V or more.

A functional layer other than the above functional layer is exemplified by a gas barrier unit consisting of an inorganic layer and an organic layer, and a layer having another function. For example, between the barrier laminate 1 and the adhesive layer 5, and/or between the barrier laminate 11 and the adhesive layer 5 in FIG. 3, an easy adhesive layer may be provided.

The method for laminating the first barrier laminate and the second barrier laminate can be known methods. Those barrier laminates may be preferably laminated by coating an adhesive on the side of the first barrier laminate unit and sticking the second barrier laminate thereto with nip rollers.

### Water Vapor Permeability

The protection sheet for a solar cell in the invention preferably have a water vapor permeability of 0.05 g/m²·day or less, more preferably a water vapor permeability of 0.005 g/m²·day or less. The water vapor permeability was measured using AQUATRAN manufactured by MOCON at 40° C. at relative humidity (RH) of 90%.

### Solae Cell

The protection sheet for a solar cell can be used for solar cell devices. The solar cell generally has an active part which practically operates as a solar cell between a pair of substrates. In the invention, the protection sheet for a solar cell of the invention may be used as one or both of the pair of substrates. The solar cell devices for which the protection sheet for a solar cell of the invention is favorably used are not specifically defined. For example, they include single crystal silicon-based solar cell devices, polycrystalline silicon-based solar cell devices, single-junction or tandem-structure amorphous silicon-based solar cell devices, gallium-arsenic (GaAs), indium-phosphorus (InP) or the like III-V Group compound semiconductor-based solar cell devices, cadmium-tellurium (CdTe) or the like II-VI Group compound semiconductor-based solar cell devices, copper/indium/selenium (CIS-based), copper/indium/gallium/selenium (CICS-based), copper/indium/gallium/selenium/sulfur (CIGSS-based) or the like Group compound semiconductor-based solar cell devices, dye-sensitized solar cell devices, organic solar cell devices, etc. Above all, in the invention, the solar cell devices are preferably copper/indium/selenium (CIS-based), copper/indium/gallium/selenium (CIGS-based), copper/indium/gallium/selenium/sulfur (CIGSS-based) or the like Group compound semiconductor-based solar cell devices.

In addition to the above, the description in JP-A-2009-38236 may be referred without diverting the scope of the invention.

### EXAMPLES

The characteristics of the invention are described more concretely with reference to the following Examples. In the following Examples, the material used, its amount and the ratio, the details of the treatment and the treatment process may be suitably modified or changed not overstepping the sprit and the scope of the invention. Accordingly, the invention should not be limitatively interpreted by the Examples mentioned below.

### <Measurement of Glass-Transition Temperature (Tg)>

An organic layer of protection sheets in the following examples was sampled and its Tg was measured using the differential scanning calorimeter (DSC6200, manufactured by Seiko Instruments Inc.) under nitrogen atmosphere at a elevating temperature of 10° C./min.

### <Water Vapor Permeability>

The water vapor permeability of protection sheets in the following examples was measured using AQUATRAN manufactured by MOCON as a water vapor permeability measuring instrument at 40° C. at 90% RH.

### <Heat Cycle Test (HC)>

Heat cycle test was carried out according to IEC61215/61646. Specifically, the sample was put into an environmental tester (manufactured by ESPEC Corp., PSL-2K) and stored at 90° C. for 20 minutes and −40° C. for 20 minutes alternately. 200 cycles of the above storage was repeated at a temperature change ratio of 87° C. per hour. Then, the water vapor permeability of the sample was measured.

### Example 1

On a PET film having a thickness of 125 μm (manufactured by Toray Industries, Inc., Rumilar S10), a 40% ethanol solution comprising acrylate (manufactured by Daicel-Cytec Company Ltd., Ebecryl EB3702) and an polymerization initiator (manufactured by Chiba, IRGACURE907) was prepared by using methylethylketone so that a film to be formed has a dried film thickness of 1000 nm. The film was irradiated and cured at UV irradiation dose of 0.5 J/cm² under atmosphere having an oxygen concentration of 100 ppm, to thereby form the organic layer.

On the organic layer, a deposit film of silicon oxide (inorganic layer) was formed with the deposition apparatus capable of depositing by plasma assist in the system of EB+ ion gun (manufactured by Shincron Co., Ltd., ACE1350IAD) according to the following condition:
ion assisted voltage: 900 V,
oxygen gas flow: 50 sccm,
argon gas flow: 8 sccm
deposit material: SiO (manufactured by OSAKA Titanium Technologies Co., Ltd.)

The obtained film was called as A-1. The formation speed was 5 nm/sec and the thickness of the inorganic layer was 50 nm.

Then, two of the films A-1 were dry-laminated so that the deposit films face to each other. The adhesive used herein was Seika Bond manufactured by Dainichi Seika. Kogyo k.K. The adhesive comprises E-372 as the main ingredient and C-76-2.0 as the curing agent. The main ingredient and the curing agent were weighted at the ratio by weight of 17:2, diluted with ethyl acetate by 10 times. The adhesive was coated with the spin coater. For changing the concentration of the adhesive, ethyl acetate was used as diluent. The solvent of the adhesive solution was dried at 90° C. for 5 minutes, and then, laminated by passing rip roller of which temperature was 70° C. The aging of the obtained film was carried out at 40° C. for 48 hours. Thus, the back sheet sample for the solar cell BS-1 was formed. The adhesive layer of the obtained film had a thickness of 5 μm.

### Example 2

A film A-2 and a back sheet BS-2 each were formed according to the same method as in Example 1, except that the organic layer in Example 1 was replaced with the following organic layer.

### (Organic Layer)

An organic solvent-soluble polyester resin (VYLON 103, manufactured by Toyobo Co., Ltd., Tg=47° C.) was solved in methylethylketone (MEK), coated with a wire bar and dried by blast at 90° C. for 5 minutes. The organic layer had a thickness of about 0.5 μm.

### Example 3

A film A-3 and a back sheet BS-3 each were formed according to the same method as in Example 1, except that the organic layer was formed by coating polyester A (Vylnal MD-1100, manufactured by Toyobo Co., Ltd., Tg=40° C.) with a wire bar and dried by blast at 160° C. for 5 minutes. The organic layer had a thickness of about 0.5 μm.

### Example 4

Films A-4 to A-13 and back sheets BS-4 to BS-13 each were formed according to the same method as in Example 3, except that the substrate film and/or the organic layer was replaced as shown in Table 1.

### Example 5

Films B-1 to B-3 each were formed according to the same method in the films A-1, A-2 and A-5, except that the substrate film was replaced with a white color PET having a thickness of 125 μm (manufactured by Toray Industries, Inc., E20).

The films A-1, A-2 and A-5 each were laminated to the films B-1 to B-3, respectively, so that the deposit layers face to each other by the dry lamination method described in Example 1, to thereby form BS-21, BS-22, and BS-25.

### Comparative Example 1

A film RA-1 and a back sheet RBS-1 each were formed according to the same method as in Example 2, except that the organic layer was replaced with a layer of polyester D (polyester series aqueous dispersed substance, Vylonal MD-1480, manufactured by Toyobo Co., Ltd., Tg=20° C.).

### Comparative Example 2

A film RA-2 and a back sheet RBS-2 each were formed according to the same method as in Example 2, except that the organic layer was formed using a primer composition comprising polyester polyol having a glass transition temperature (Tg) of 7° C., acrylpolyol having a Tg of 85° C. and isocyanate (adductus of IPDI) at a ratio by weight of 1:3:1 (the solvent was ethyl acetate). The layer had a Tg of about 10° C.

### Comparative Example 3

A film RA-3 and a back sheet RBS-3 each were formed according to the same method as in Example 2, except that the organic layer was replaced with the following organic layer.

### (Organic Layer)

A primer layer 1 was provided so as to comprises polyester polyol having a glass transition temperature (Tg) of 7° C., acrylpolyol having a Tg of 85° C. and isocyanate (adductus of IPDI) at a ratio by weight of 3:1:4 (the solvent was ethyl acetate). Then, a primer layer 2 was provided on the primer layer 1 so as to comprises acrylpolyol having a Tg of 62° C. and isocyanate (adductus of IPDI) at a ratio by weight of 5:1 (solid content ratio). The primer layer 1 had a Tg of about 15° C. and the primer layer 2 had a Tg of about 35° C.

### Example 6

A film A-14 and a back sheet BS-14 each were formed according to the same method as in Example 1, except that the PET film was replaced with a polylactate film having a thickness of 125 μm which was formed according to the method disclosed in JP-A-7-205278.

### Example 7

A film A-15 and a back sheet BS-15 each were formed according to the same method as in Example 4, except that the film A-5 was replaced with a polylactate film having a thickness of 125 μm which was formed according to the method disclosed in JP-A-7-205278.

### Example 8

A film A-16 and a back sheet BS-16 each were formed according to the same method as in Example 2, except that the organic layer was replaced with the following organic layer.

### (Organic Layer)

The organic layer was formed by coating methylene chloride solution of polylactate manufactured by Ardrich, as typical polyester which does not have an aromatic ring. The organic layer had a thickness of about 0.5 μm.

### (Used Material)

PEN film: Teonex Q65FA, manufactured by Teijin DuPont Films Japan Ltd.
PMMA film: ACRYPLEN HEXN47 manufactured by Mitsubishi Rayon Co., Ltd.
PS film: OPS film manufactured by Asahi Kasei Chemicals Corporation
PC film: Pure-Ace manufactured by Teijin Chemicals Ltd.

Those films each have a thickness of about 100 μm and were cut into A4 size and subjected the surfaces thereof to plasma treatment at an oxygen/argon ratio of 10/2 at pressure of 2.5 Pa at 100 W for 15 seconds.

Polyester A: Vylonal MD1100 (Tg=40), manufactured by Toyobo Co., Ltd
Polyester B: Vylonal MD1200 (Tg=67), manufactured by Toyobo Co., Ltd.
Polyester C: PLAS COAT Z-687 (Tg=110), manufactured by Goo Chemical Co., Ltd.
Acryl A: DIANAL manufactured by Mitsubishi Rayon Co., Ltd.
Acryl B: JURYMER ET-410 (Tg=44), manufactured by Toyobo Co., Ltd.
SBR A: Zeon Corporation LX433C (Tg=50), manufactured by Zeon Corporation
Polyester D: Vylonal MD1480 (Tg=20), manufactured by Toyobo Co., Ltd.

TABLE 1

| | | Organic layer | | | | Water vapor permeability | | |
|---|---|---|---|---|---|---|---|---|
| | | | | Layer | | [g/m2 · day] | | |
| | Substrate | | | thickness | Tg | | After HC | |
| Film No. | film | Composition | Classification | [μm] | [° C.] | Initial | testing | Remark |
| A-1 | PET | Refer to | Solvent | 0.5 | 50 | 0.050 | 0.065 | Invention |
| | | Example 1 | | | | | | |
| A-2 | PET | Refer to | Solvent | 0.5 | 47 | 0.050 | 0.070 | Invention |
| | | Example 2 | | | | | | |
| A-3 | PET | Polyester A | Aqueous | 0.5 | 40 | 0.060 | 0.075 | Invention |
| A-4 | PET | Polyester B | Aqueous | 0.5 | 67 | 0.055 | 0.065 | Invention |
| A-5 | PET | Polyester C | Aqueous | 0.5 | 110 | 0.045 | 0.045 | Invention |
| A-6 | PEN | Polyester C | Aqueous | 0.5 | 110 | 0.045 | 0.045 | Invention |
| A-7 | PET | acryl A | Aqueous | 0.5 | 68 | 0.055 | 0.095 | Invention |
| A-8 | PET | acryl B | Aqueous | 0.5 | 44 | 0.050 | 0.095 | Invention |
| A-9 | PET | SBR A | Aqueous | 0.5 | 50 | 0.045 | 0.100 | Invention |
| A-10 | PET | Polyester C | Aqueous | 0.1 | 110 | 0.045 | 0.085 | Invention |
| A-11 | PET | Polyester C | Aqueous | 2.9 | 110 | 0.045 | 0.065 | Invention |
| A-12 | PET | Polyester C | Aqueous | 4.2 | 110 | 0.045 | 0.075 | Invention |
| A-13 | PET | Polyester C | Aqueous | 5.6 | 110 | 0.045 | 0.095 | Invention |
| RA-1 | PET | Polyester D | Aqueous | 0.5 | 20 | 0.065 | 0.550 | Comp. |
| | | | | | | | | Example |
| RA-2 | PET | Refer to Comp. | Aqueous | 0.5 | 10 | 0.055 | 0.750 | Comp. |
| | | Example 2 | | | | | | Example |
| RA-3 | PET | Refer to Comp. | Aqueous | 0.5/0.5 | 15/35 | 0.060 | 0.600 | Comp. |
| | | Example 3 | | | | | | Example |
| RA-4 | PMMA | Polyester C | Aqueous | 0.5 | 110 | 0.055 | 1.050 | Comp. |
| | | | | | | | | Example |
| RA-5 | PS | Polyester C | Aqueous | 0.5 | 110 | 0.060 | (Peeled) | Comp. |
| | | | | | | | | Example |
| RA-6 | PC | Polyester C | Aqueous | 0.5 | 110 | 0.055 | 1.200 | Comp. |
| | | | | | | | | Example |
| A-14 | Polylactate | Refer to | Solvent | 0.5 | 50 | 0.050 | 0.085 | Invention |
| | | Example 1 | | | | | | |
| A-15 | Polylactate | Polyester C | Aqueous | 0.5 | 110 | 0.050 | 0.095 | Invention |
| A-16 | PET | Polylactate | Solvent | 0.5 | 62 | 0.055 | 0.085 | Invention |

TABLE 2

| | | Organic layer | | | | Water vapor permeability | | | |
|---|---|---|---|---|---|---|---|---|---|
| | | | | Layer | | [g/m2 · day] | | Appearance | |
| | Substrate | | | thickness | Tg | | After HC | (After HC | |
| Film No. | film | Composition | Classification | [μm] | [° C.] | Initial | testing | testing) | Remark |
| BS-1 | PET | Refer to | Solvent | 0.5 | 50 | 0.005 | 0.010 | Unchanged | Invention |
| | | Example 1 | | | | | | | |
| BS-2 | PET | Refer to | Solvent | 0.5 | 47 | 0.005 | 0.010 | Unchanged | Invention |
| | | Example 2 | | | | | | | |
| BS-3 | PET | Polyester A | Aqueous | 0.5 | 40 | 0.010 | 0.020 | Unchanged | Invention |
| BS-4 | PET | Polyester B | Aqueous | 0.5 | 67 | 0.010 | 0.015 | Unchanged | Invention |
| BS-5 | PET | Polyester C | Aqueous | 0.5 | 110 | 0.005 | 0.010 | Unchanged | Invention |
| BS-6 | PEN | Polyester C | Aqueous | 0.5 | 110 | 0.005 | 0.010 | Unchanged | Invention |
| BS-7 | PET | acryl A | Aqueous | 0.5 | 68 | 0.010 | 0.025 | Unchanged | Invention |
| BS-8 | PET | acryl B | Aqueous | 0.5 | 44 | 0.005 | 0.015 | Unchanged | Invention |
| BS-9 | PET | SBR A | Aqueous | 0.5 | 50 | 0.005 | 0.010 | Unchanged | Invention |
| BS-10 | PET | Polyester C | Aqueous | 0.1 | 110 | 0.005 | 0.020 | Unchanged | Invention |
| BS-11 | PET | Polyester C | Aqueous | 2.9 | 110 | 0.005 | 0.005 | Unchanged | Invention |
| BS-12 | PET | Polyester C | Aqueous | 4.2 | 110 | 0.005 | 0.015 | Unchanged | Invention |
| BS-13 | PET | Polyester C | Aqueous | 5.6 | 110 | 0.005 | 0.025 | Unchanged | Invention |
| BS-21 | PET* | Refer to | Solvent | 0.5 | 50 | 0.005 | 0.010 | Unchanged | Invention |
| | | Example 1 | | | | | | | |
| BS-22 | PET* | Refer to | Solvent | 0.5 | 47 | 0.005 | 0.015 | Unchanged | Invention |
| | | Example 2 | | | | | | | |
| BS-25 | PET* | Polyester C | Aqueous | 0.5 | 110 | 0.005 | 0.010 | Unchanged | Invention |
| RBS-1 | PET | Polyester D | Aqueous | 0.5 | 20 | 0.015 | 0.090 | Peeled | Comp. |
| | | | | | | | | | Example |
| RBS-2 | PET | Refer to Comp. | Aqueous | 0.5 | 10 | 0.010 | 0.155 | Peeled | Comp. |
| | | Example 2 | | | | | | | Example |
| RBS-3 | PET | Refer to Comp. | Aqueous | 0.5 | 15/35 | 0.010 | 0.095 | Peeled | Comp. |
| | | Example 3 | | | | | | | Example |
| RBS-4 | PMMA | Polyester C | Aqueous | 0.5 | 110 | 0.010 | 0.205 | Unchanged | Comp. |
| | | | | | | | | | Example |
| RBS-5 | PS | Polyester C | Aqueous | 0.5 | 110 | 0.015 | Impossibility | Peeled | Comp. |
| | | | | | | | of measurement | | Example |
| RBS-6 | PC | Polyester C | Aqueous | 0.5 | 110 | 0.010 | 0.450 | Unchanged | Comp. |
| | | | | | | | | | Example |
| BS-14 | Polylactate | Refer to | Solvent | 0.5 | 50 | 0.010 | 0.020 | Unchanged | Invention |
| | | Example 1 | | | | | | | |
| BS-15 | Polylactate | Polyester C | Aqueous | 0.5 | 110 | 0.010 | 0.020 | Unchanged | Invention |
| BS-16 | PET | Polylactate | Solvent | 0.5 | 62 | 0.015 | 0.025 | Unchanged | Invention |

In the above table, “*” means that the second substrate of the second barrier laminate facing the first barrier laminate is a white PET film.

As is clear from the above result, it was found that the film having the organic layer comprising polymer material having Tg of 40° C. or more as the main ingredient has high resistance for change against temperature and humidity. However, it was found that, when the organic layer comprising polymer material having Tg of 40° C. or more as the main ingredient is laminated on PMMA, PS or PC, the resistance for change against temperature and humidity is poor. It was found that the protection sheet for a solar cell of the invention has remarkably less deterioration of the barrier property thereof even after the protection sheet was subjected to the heat cycle test.

The film comprising the aqueous latex-containing organic layer and the film comprising the solvent showed nearly common effect. This shows that the invention can take advantage of the aqueous latex because environment load thereof is low and explosion-proof apparatus thereto is not required.

Especially, it was found that, when the film comprises a substrate film comprising polyester comprising an aromatic group and an organic layer comprising polyester comprising an aromatic group, the film is further excellent in gas barrier property and durability.

### INDUSTRIAL APPLICABILITY

The invention can provide a protection sheet for a solar cell which can maintain sufficient barrier property if the organic layer of the protection sheet is formed by using an aqueous dispersion comprising polymer material, and if the protection sheet is repeatedly exposed to high temperature and low temperature alternately. The conventional protection sheets for a solar cell cannot maintain sufficient barrier property thereof unless the organic layer thereof is provided by using a coating solution in which organic polymer is solved in organic solvent. The invention responds to VOC problems and explosion-proof problems and is good for environment.

In addition, the invention can enhance the durability of the protection sheet in the case where the protection sheet is repeatedly used under high temperature and low temperature alternately by using polymers in the same series as polymer material contained in the polyester substrate and the organic layer.

The protection sheet for a solar cell of the invention can be produced at low cost and at less environment load. The invention is remarkably advantageous from the viewpoint that the protection sheet can be produced without UV irradiation.

The present disclosure relates to the subject matter contained in Japanese Patent Application No. 032167/2010 filed on Feb. 17, 2010, which is expressly incorporated herein by reference in their entirety. All the publications referred to in the present specification are also expressly incorporated herein by reference in their entirety.

The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims set forth below.

What is claimed is:

1. A barrier laminate comprising a polyester substrate film, an organic layer directly on the surface of the polyester substrate film and an inorganic layer directly on the surface of the organic layer, wherein the organic layer comprises a polymer material having a glass-transition temperature of 40° C. or more as the main component.

2. A protection sheet for a solar cell comprising a barrier laminate, wherein the barrier laminate comprises a polyester substrate film, an organic layer directly on the surface of the polyester substrate film and an inorganic layer directly on the surface of the organic layer, and the organic layer comprises polymer material having a glass-transition temperature of 40° C. or more as the main component.

3. The protection sheet for a solar cell according to claim 2, wherein the polymer material in the organic layer is polyester.

4. The protection sheet for a solar cell according to claim 2, wherein the polymer material in the organic layer is aromatic polyester.

5. The protection sheet for a solar cell according to claim 2, wherein the polyester substrate film comprises aromatic polyester.

6. The protection sheet for a solar cell according to claim 2, wherein the polymer material in the organic layer is aromatic polyester and the polyester substrate film comprises aromatic polyester.

7. The protection sheet for a solar cell according to claim 2, wherein the inorganic layer comprises silicon oxide, aluminium oxide, or a mixture thereof as the main component.

8. The protection sheet for a solar cell according to claim 2, wherein the polyester substrate film comprises polyethylene terephthalate and/or polyethylene naphthalate.

9. The protection sheet for a solar cell according to claim 2, wherein the organic layer has a thickness of 0.1 to 3 μm.

10. The protection sheet for a solar cell according to claim 2, wherein the inorganic layer has a thickness of 30 to 200 nm.

11. The protection sheet for a solar cell according to claim 2, wherein the substrate film has a thickness of 50 to to 200 μm.

12. The protection sheet for a solar cell according to claim 2, wherein the organic layer has a thickness of 0.1 to 3 μm, the inorganic layer has a thickness of 30 to 200 nm, and the substrate film has a thickness of 50 to to 200 μm.

13. The protection sheet for a solar cell according to claim 2, wherein the polymer material in the organic layer has a glass-transition temperature of 60 to 120° C.

14. The protection sheet for a solar cell according to claim 2, wherein the organic layer has a thickness of 0.1 to 3 μm, the inorganic layer has a thickness of 30 to 200 nm, the substrate film has a thickness of 50 to to 200 μm, the polymer material in the organic layer is aromatic polyester, and the polyester substrate film comprises aromatic polyester.

15. The protection sheet for a solar cell according to claim 2, which further comprises a second barrier laminate comprising a polymer substrate film, an organic layer directly on the surface of the polymer substrate film and an inorganic layer directly on the surface of the organic layer; and wherein the inorganic layer of the barrier laminate and the inorganic layer of the second barrier laminate face to each other.

16. The protection sheet for a solar cell according to claim 15, wherein the polymer substrate is a polyester substrate film.

17. The protection sheet for a solar cell according to claim 2, which is free from organic solvent.

18. A solar cell device comprising a protection sheet for a solar cell comprising a barrier laminate, wherein the barrier laminate comprises a polyester substrate film, an organic layer directly on the surface of the polyester substrate film and an inorganic layer directly on the surface of the organic layer, and the organic layer comprises polymer material having a glass-transition temperature of 40° C. or more as the main component.

19. A method for manufacturing a protection sheet for a solar cell comprising a barrier laminate, which comprises applying a composition for an organic layer on a substrate film, and wherein the composition for an organic layer is aqueous dispersion, and the barrier laminate comprises a polyester substrate film, an organic layer directly on the surface of the polyester substrate film and an inorganic layer directly on the surface of the organic layer, and the organic layer comprises polymer material having a glass-transition temperature of 40° C. or more as the main component.

20. The method for manufacturing a protection sheet for a solar cell according to claim 19, which comprises forming the inorganic layer by vapor deposition method.
